(19) United States
(12) Patent Application Publication
(10) Pub. No.: US 2026/0098747 A1
(43) Pub. Date: Apr. 9, 2026

(54) Sensor element

(71) Applicant: Balluff GmbH, Neuhausen auf den Fildern (DE)

(72) Inventors: Ümit Koyuncu, Ostfildern (DE); Marton Palmann, Neuhausen (DE)

(73) Assignee: Balluff GmbH, Neuhausen auf den Fildern (DE)

(21) Appl. No.: 19/307,995

(22) Filed: Aug. 22, 2025

(30) Foreign Application Priority Data
Oct. 9, 2024 (DE) 102024129145.1

(51) Int. Cl. G01D 5/20

(52) U.S. Cl. CPC G01D 5/204

(57) ABSTRACT

A sensor element has several planes (E1-E7) arranged orthogonal to a sensor axis (A). A coil (21-23) which is surrounded by a first shielding ring (41-43) is arranged in at least one first plane (E1-E3). The sensor element (10) further has at least one second shielding ring (44-47). In each case, each second shielding ring (44-47) is arranged in a second plane (E4-E7) which does not have a coil (21-23).

### CROSS-REFERENCE TO RELATED APPLICATIONS

The present application claims priority to German Application No. 102024129145.1 filed Oct. 9, 2024, the disclosure of which is incorporated by reference in its entirety.

### FIELD OF INVENTION

The present invention relates to a sensor element.

### PRIOR ART

When installing inductive sensors in metallic surroundings, depending on the installation situation there is the danger that the surrounding material is detected instead of an object to be detected. The surrounding material can in particular be a metal nut or an installation medium, such as aluminium, for example. This problem can be countered, for example, whereby the sensor is provided with an electromagnetically well-shielding housing, which consists of brass, for example. However, a shielding housing of such type is more expensive than a housing made from stainless steel, for example. Similarly, only by using a large quantity of expensive stainless steel can all coils of the inductive sensor be surrounded by a single shielding ring made from copper, which is longer than the sensor element. Furthermore, displacement of the copper ring over the service life of the sensor can lead to failure of the latter.

Steering the magnetic field of an inductive sensor in order to exclude objects behind the coil or the coils of the sensor from being detected and to only recognise those in front of the coil or coils can be achieved by using a ferrite core. However, if a ferrite core is used, the sensor cannot be designed to be resistant to magnetic fields.

US 2020/0231582 A1 describes an angle sensor having several coils arranged in superimposed planes. The coil planes are followed by several EMI shielding layers, which are arranged between the coils and control electronics of the sensor.

It is an object of the present invention to provide a sensor element which can be installed in metallic surroundings, without it detecting the installation material. This should be possible without using a large quantity of stainless steel to shield the sensor element, and without causing a sharp deterioration of the signal quality of the sensor element.

### DISCLOSURE OF THE INVENTION

This object is solved according to the invention by a sensor element, in particular an inductive sensor element, which has several planes arranged orthogonal to a sensor axis. A coil which is surrounded by a first shielding ring is arranged in at least one first plane. A shielding ring of such type is also referred to as a short circuit ring and serves to electromagnetically shield the coil. In order to enable one embodiment of the sensor element as an inductive sensor element, in particular several first planes are provided with one respective coil surrounded by a first shielding ring. Furthermore, the sensor element has at least one second shielding ring. In each case, each second shielding ring is arranged in a second plane which does not have a coil. It has been found that reliable shielding from an installation material can already be achieved in that, on the one hand, all coils of the sensor element are each surrounded by a shielding ring and furthermore one or more further planes having shielding rings are arranged behind the coil or behind the coils. In this case, each plane can in particular be a printed circuit board or a layer inside a multilayer printed circuit board. The coils are therefore print coils and the shielding rings are printed into the first planes and second planes. These shielding rings consist in particular of copper. The amount of stainless steel required for this purpose is significantly lower than if a massive shielding ring extending across and beyond the first planes were to be used, or even if the coils were to be installed in a shielding housing consisting of copper or a coper alloy, such as brass.

In a preferred embodiment of the sensor element, all shielding rings have an identical outer diameter. As a result, they define the outer edge of the sensor element, which can be surrounded by a circular-cylindrical housing consisting of stainless steel.

The inner diameter of the first shielding rings is specified by the diameter of the coils. Fundamentally, it is possible that all second shielding rings have the same inner diameter as the first shielding rings. Preferably, however, at least one second shielding ring has an inner diameter which is smaller than an inner diameter of a first shielding ring. Therefore, not only is a good radial shielding of the coils achieved, but the shielding ring having the small inner diameter furthermore causes axial shielding in the direction of an electronic controller connected to the coils. In particular, this controller can be arranged on the side of the second shielding rings facing away from the coils.

In another preferred embodiment of the sensor element, all first shielding rings and at least one second shielding ring have a first outer diameter. However, at least one second shielding ring has a second outer diameter which is smaller than the first outer diameter. This second shielding ring having the second outer diameter furthermore has a smaller inner diameter than the second shielding ring having the first outer diameter. This second shielding ring having the second outer diameter is the second shielding ring which is furthest removed from the first shielding ring or the first shielding rings. This embodiment enables focused shielding on the sensor axis. In this case, the sensor element is influenced less by the small second outer diameter than if this second shielding ring were also to have the first outer diameter. The sensitivity to an object to be detected on the side of the coil or the coils facing away from the second shielding rings therefore increases. This can be used to achieve shielding against a highly disruptive, small conductive object, which is a component of the sensor element and is located on the sensor axis.

In the two preferred embodiments of the sensor element, it is further preferred that when several second shielding rings are present, an inner diameter of the second shielding rings becomes smaller as the distance from the at least one first coil increases. Therefore, on the one hand, good shielding can be achieved in the axial direction, without, on the other hand, reducing the sensitivity of the coil system by second shielding rings, which already have a small inner diameter near to the at least one first coil.

At least one distance between a first plane and a second plane is at least 20% of an outer diameter of a first shielding ring. In particular, this is the distance between the outermost first plane and the outermost second plane of the sensor element. By arranging the last second shielding ring at such a large distance from the coil or the coils, this ring can be designed to have a small inner diameter in order to achieve good axial shielding, without adversely affecting the sensitivity of the sensor element in this case.

A thickness of the shielding rings is preferably in the range from 10 μm to 105 μm. In this case, the dimension along the sensor axis is understood as the thickness. Particularly preferably, all shielding rings have the same thickness in this case. This thickness is suitable for effecting reliable radial shielding of the coils in the first plane. In this case, it is advantageous for the sensitivity of the coil system to design the second shielding rings with the same thickness as the first shielding rings.

A distance between a first plane and a second plane adjacent to this is preferably in the range from 70 μm to 120 μm. A distance between two adjacent second planes is similarly preferably in the range from 70 μm to 120 μm. This value range is selected so that, on the one hand, good radial shielding is achieved, but on the other hand, so that an increase in the number of layers and thus of the costs of the sensor element due to narrow distances is avoided. Particularly preferably, all these distances have the same value. Fundamentally, however, the distances can also all be selected to be different. This applies in particular for the distances between the second planes, in order to optimise the signal sensitivity and shielding effect. The larger the distance of the second planes, the lower the shielding effect is, but also the higher the signal sensitivity of the sensor element.

A width of each second shielding ring is preferably in the range from 70 μm to half of its outer diameter. Here, the width is understood to mean the dimension in the second plane, i.e. the difference between the inner diameter and the outer diameter of the second shielding ring. While a width of each first shielding ring is preferably in the range from 70 μm to 120 μm, the second shielding rings can have a significantly larger width in order to thereby achieve good axial shielding.

In particular, when the sensor element is to be designed as an inductive sensor, it is preferred that this has three coils. In this case, particularly preferably, a first receiving coil, a transmitter coil and a second receiving coil are arranged in succession along the sensor axis. The two receiving coils are electrically connected to each other. The set-up as receiving coils is effected in particular by connecting the coil to a voltage measuring device. The set-up as a transmitter coil, which is insulated electrically from the two receiving coils, is effected in particular by electrically connecting this coil to a pulse former. Such an inductive sensor enables all metallic objects to be recognised without the reduction factor with the same switching distance. This characteristic is advantageous in applications in which the material of the objects to be detected may vary or when non-ferrous metals are to be detected with a high switching distance.

The shielding according to the invention also then lends a high sensitivity to the sensor element, even when it is installed in a metallic material. Its function is not disrupted by strong electromagnetic fields. Therefore, for example, it can be used in welding systems.

### BRIEF DESCRIPTION OF THE DRAWINGS

Exemplary embodiments of the invention are represented in the drawings and are explained in more detail in the following description.

FIG. 1 schematically shows a coil arrangement of an inductive sensor according to an exemplary embodiment of the invention.

FIGS. 2a to 2c each show three different installation situations of an inductive sensor according to the prior art in a sectional representation.

FIGS. 3a to 3c each show in a sectional representation, an installation situation of an inductive sensor according to an exemplary embodiment of the invention.

FIG. 4 shows a sectional representation of an inductive sensor according to an exemplary embodiment of the invention.

FIG. 5 shows a sectional representation of an inductive sensor according to another exemplary embodiment of the invention.

FIG. 6 shows a detailed excerpt from FIG. 5.

FIG. 7 shows a sectional representation of an inductive sensor according to yet another exemplary embodiment of the invention.

FIG. 8 shows a detailed excerpt from FIG. 7.

### EXEMPLARY EMBODIMENTS THE INVENTION

FIG. 1 shows a coil arrangement of an inductive sensor element 10, which is designed as a proximity switch. This has three coils 21-23. The first coil 21 and the third coil 23 are electrically connected to each other. Furthermore, in each case they are connected to a voltage measuring device 11 in order to scan the electrical voltage. The second coil 22 is arranged between these two coils 21, 23. It is connected to a pulse former 12 of an oscillator. The first coil 21 and the third coil 23 serve as receiving coils, and the second coil 22 serves as a transmitter coil. When a metallic object 30 is brought close to the sensor element 10 and moves towards the sensor element 10 along a section s, the object 30 is detected when the distance falls below a switching distance.

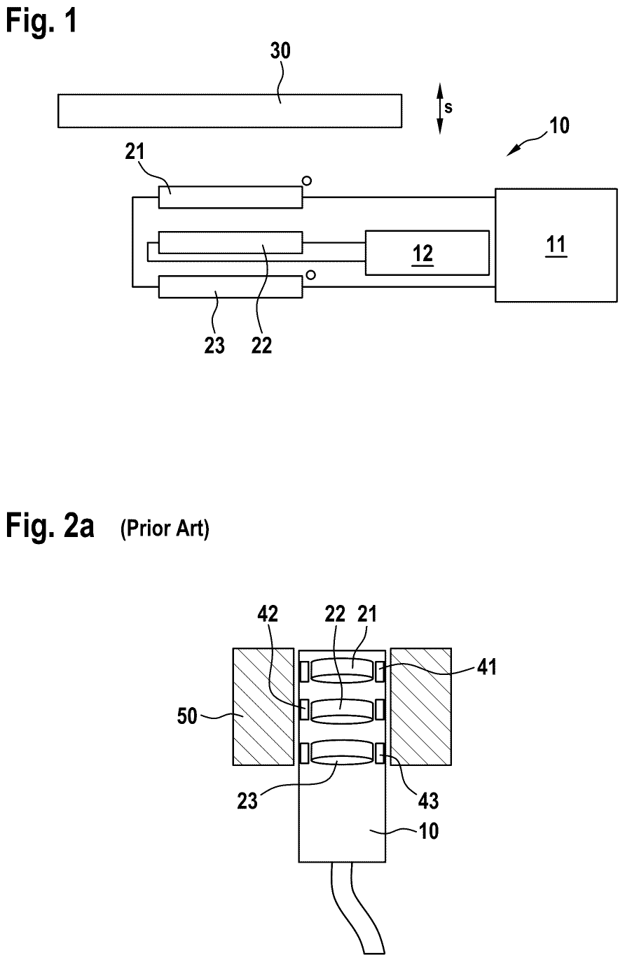

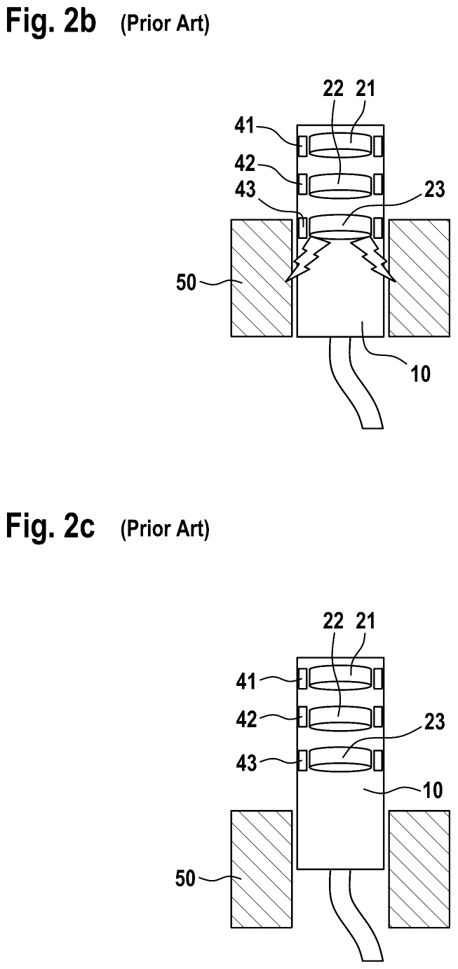

In a sensor element 10 of such type, each of the coils 21-23 can be surrounded by a copper shielding ring 41 to 43. Several different installation situations, in which the sensor element 10 is installed in a metallic surroundings 50, are represented in FIGS. 2a to 2c. Whereas in the installation situations shown in FIGS. 2a and 2c, the coils 21-23 do not detect the surrounding material 50, such detection does occur in the installation situation according to FIG. 2b.

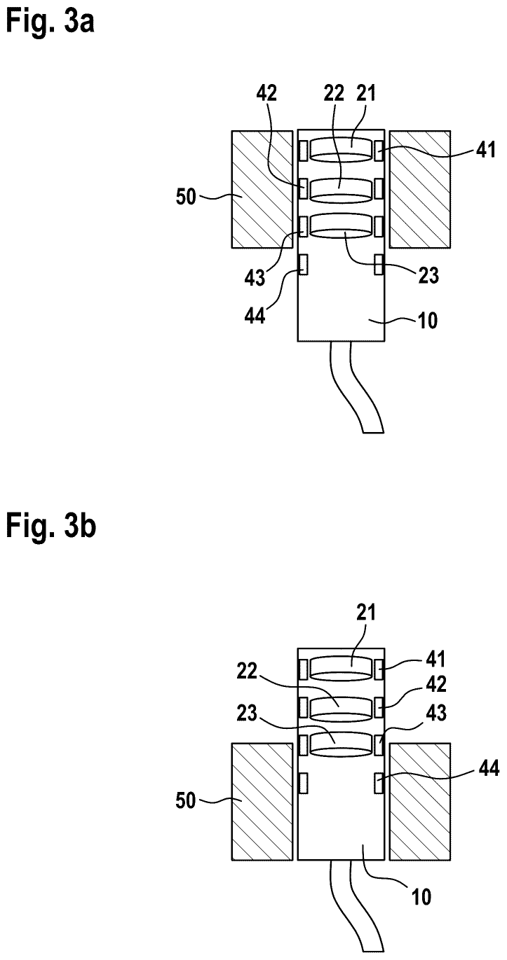

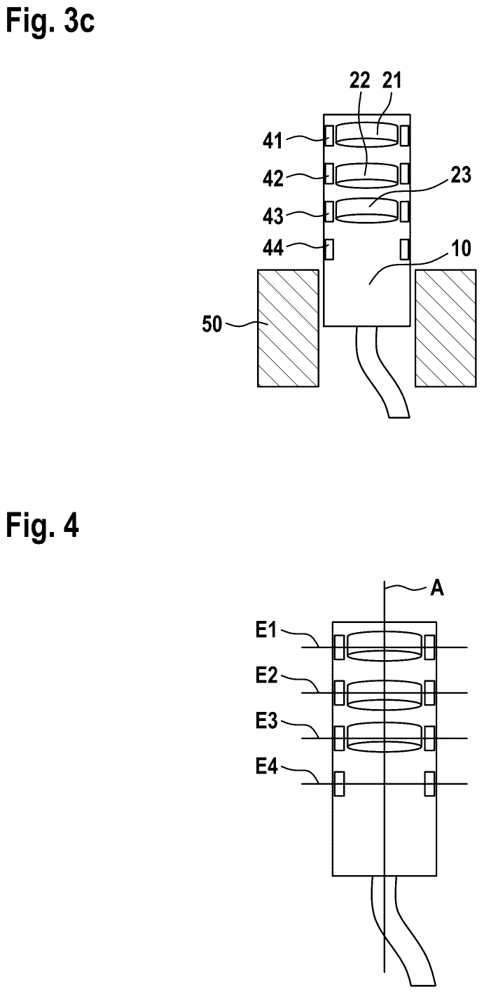

In a first exemplary embodiment of the invention, it is therefore provided that, along with the three shielding rings 41-43 which surround the three coils 21-23, a fourth shielding ring 44 is provided. This shields the coils 21-23 additionally in the direction of the sensor element 10 facing away from the detection direction. FIGS. 3a to 3c show that in all three installation situations, which have been represented in FIGS. 2a to 2c for the sensor element 10 not according to the invention, there is sufficient shielding from the metallic surroundings 50.

FIG. 4 shows a detailed representation of the sensor element 10 according to the first exemplary embodiment of the invention. The coils 21-23 are arranged along a sensor axis A. Each of the coils 21-23 lies together with the shielding ring 41 to 43 surrounding it in its respective own plane E1-E3 which is orthogonal to the sensor axis A. A fourth plane E4 which has no coils follows these three planes E1-E3. The fourth shielding ring 44 is arranged in this fourth plane. The fourth plane E4 is similarly orthogonal to the sensor axis A and thus runs parallel to the remaining planes E1-E3. In this first exemplary embodiment of the sensor element 10, all shielding rings 41-44 have the same inner diameter and the same outer diameter. In this, as in all the following exemplary embodiments, the outer diameters of the coils 21-23 are identical.

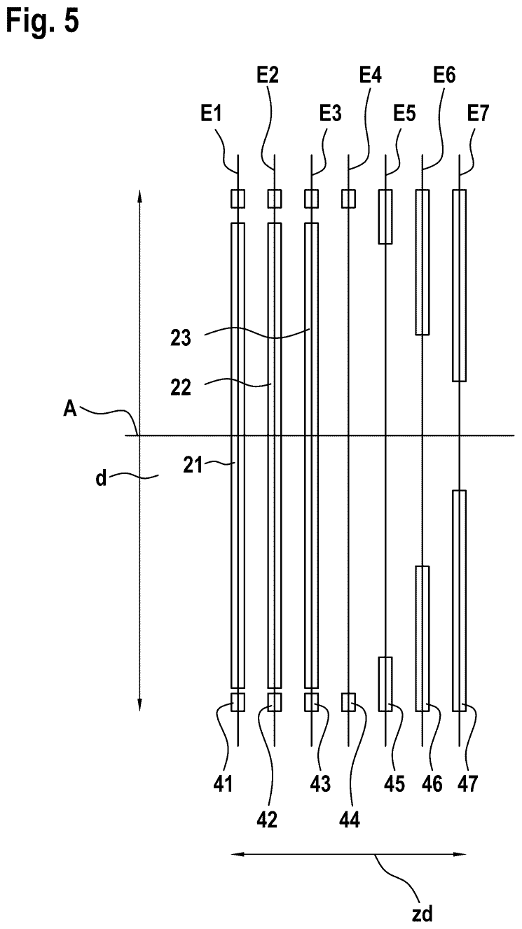

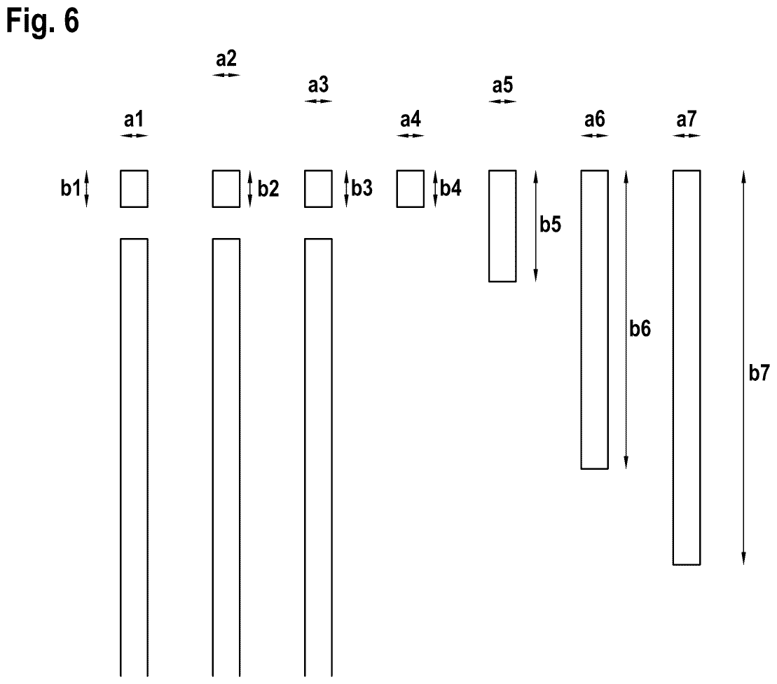

A second exemplary embodiment of the sensor element 10 according to the invention is represented in FIGS. 5 and 6. This has an arrangement and dimensioning of the coils 21-23 and the first four shielding rings 41-44 which matches the first exemplary embodiment. However, three further shielding rings 45-47 are provided, which are arranged in succession in three further planes E5-E7. These planes E5 to E7 are similarly arranged orthogonal to the sensor axis A and parallel to the plane E1-E4. While the outer diameter d of all shielding rings 41-47 is 9 mm for example, the distance zd between the first plane E1 and the seventh plane E7 is 2.4 mm, for example. Thus, this distance zd is greater than 20% of the outer diameter d. All shielding rings 41-47 have a thickness a1-a7 which in each case is 50 μm, for example. A width b1-b4 of each of the first four shielding rings 41 to 44 is 75 μm, for example. The width b5 of the fifth shielding ring 45 is 150 μm, for example. The width b6 of the sixth shielding ring 46 is 300 μm, for example. The width b7 of the seventh shielding ring 47 is 450 μm, for example. The distances between two adjacent planes are in each case 100 μm, for example. Due to the width b4-b7 of the shielding rings 44-47 increasing with an increasing distance from the coils 21-23, the inner diameter thereof decreases, and good axial shielding of the coils 21-23 is achieved, without negatively influencing the sensor sensitivity in the process.

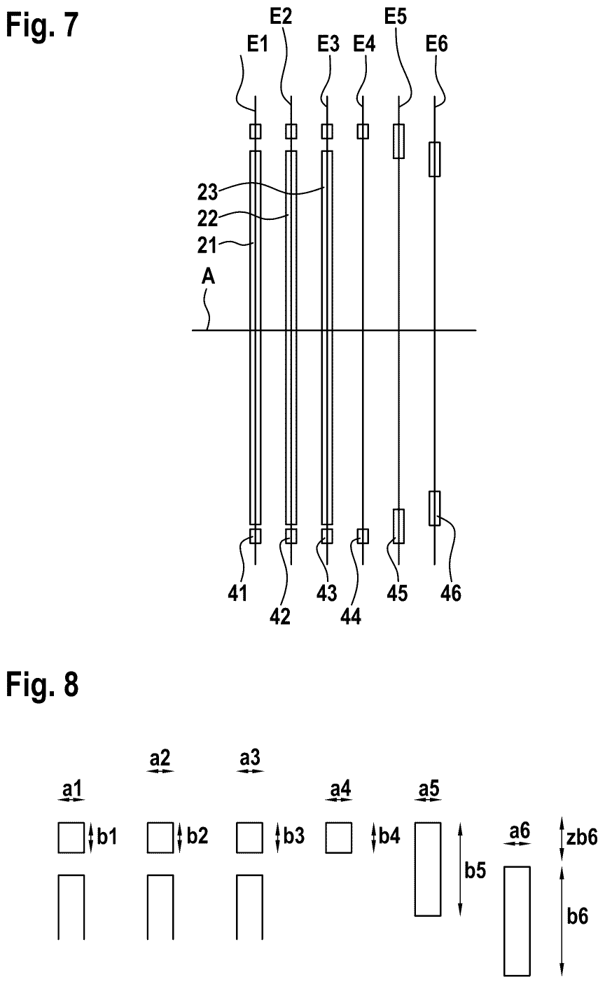

A third exemplary embodiment of the sensor element 10 according to the invention is represented in FIGS. 7 and 8. This matches the second exemplary embodiment with regard to the dimensions, the dimensioning and positioning of the coils 21-23 and the first five shielding rings 41-45 in the first five planes E1-E5. However, instead of the two further shielding rings 46, 47 of the second exemplary embodiment, this sensor element only has one further shielding ring 46 in a plane E6, which differs from the shielding ring 46 of the second exemplary embodiment. Its outer diameter is reduced to 150 μm in comparison to the remaining shielding rings 41 to 45, whereby its outer radius is reduced to a value zb6 of 75 μm. This corresponds to the width b1-b4 of the first four shielding rings 41-44. Therefore, the sixth shielding ring 46 does not overlap with these four first shielding rings 41-44 along the sensor axis A. While its thickness a6 matches with the value according to the second exemplary embodiment, its width b6 is 200 μm. Although it is therefore only 50 μm wider than the fifth shielding ring 45, it has an inner diameter which resembles that of the substantially wider sixth shielding ring of the second exemplary embodiment. The sixth shielding ring 46 is so far removed from the coils 21-23 that it is no longer of great importance for the radial shielding, and therefore the decrease of its outer diameter can be tolerated. However, because its inner diameter resembles that of the sixth shielding ring 46 of the second exemplary embodiment, similarly good axial shielding is also achieved. Therefore, not only is material saved, but also any negative influence on the sensitivity of the sensor element by this shielding ring 46 is reduced in comparison to the second exemplary embodiment.

1. Sensor element (10), having several planes (E1-E7) arranged orthogonal to a sensor axis (A), wherein a coil (21-23) which is surrounded by a first shielding ring (41-43) is arranged in at least one first plane (E1-E3), characterised in that the sensor element (10) furthermore has at least one second shielding ring (44-47), wherein in each case, each second shielding ring (44-47) is arranged in a second plane (E4-E7) which does not have a coil (21-23).

2. Sensor element (10) according to claim 1, characterised in that all shielding rings (41-47) have an identical outer diameter (d).

3. Sensor element (10) according to claim 1, characterised in that it has at least one second shielding ring (45-47), the inner diameter of which is smaller than an inner diameter of a first shielding ring (41-43).

4. Sensor element (10) according to claim 1, characterised in that all first shielding rings (41-43) and at least one second shielding ring (44-45) have a first outer diameter (d) and at least one second shielding ring (46) has a second outer diameter (d) which is smaller than the first outer diameter (d), wherein the second shielding ring (46) having the second outer diameter (d) has a smaller inner diameter than the second shielding ring (44-45) having the first outer diameter (d).

5. Sensor element (10) according to claim 3, characterised in that it has several second shielding rings (44-47), wherein an inner diameter of the second shielding rings (44-47) becomes smaller as the distance from the at least one first coil (21-23) increases.

6. Sensor element (10) according to claim 1, characterised in that at least one distance (zd) between a first plane (E1-E3) and a second plane (E4-E7) corresponds to at least 20% of an outer diameter (d) of a first shielding ring (21-23).

7. Sensor element (10) according to claim 1, characterised in that a thickness (a1-a7) of the shielding rings (41-47) along the sensor axis (A) is in the range from 10 μm to 105 μm.

8. Sensor element (10) according to one of claim 1, characterised in that a distance between a first plane (E3) and a second plane (E4) adjacent to this is in the range from 70 μm to 120 μm.

9. Sensor element (10) according to claim 1, characterised in that a distance between two adjacent second planes (E4-E7) is in the range from 70 μm to 120 μm.

10. Sensor element (10) according to claim 1, characterised in that a width (b4-b7) of each second shielding ring (44-47) in its second plane (E4-E7) is in the range from 70 μm to half of its outer diameter (d).

11. Sensor element (10) according to claim 1, characterised in that a first receiving coil (21), a transmitter coil (22) and a second receiving coil (23) are arranged in succession along the sensor axis (A), wherein the two receiving coils (21, 23) are electrically connected to each other.
